(19) United States
(12) Patent Application Publication
(10) Pub. No.: US 2006/0046382 A1
(43) Pub. Date: Mar. 2, 2006

(54) Method of forming a capacitor for a semiconductor device

(76) Inventors: Kuk-Han Yoon, Gyeonggi-do (KR); Sang-Sup Jeong, Gyeonggi-do (KR); Sung-Gil Choi, Gyeonggi-do (KR); Jong-Kyu Kim, Seoul (KR)

Correspondence Address: MARGER JOHNSON & MCCOLLOM, P.C., 210 SW MORRISON STREET, SUITE 400, PORTLAND, OR, 97204, US

(21) Appl. No.: 11/206,418

(22) Filed: Aug. 17, 2005

(30) Foreign Application Priority Data
Aug. 26, 2004 (KR) 2004-67315

(51) Int. Cl. H01L 21/8242

(52) U.S. Cl. 438/254

(57) ABSTRACT

In an embodiment, a method of forming a capacitor for a semiconductor device of which structural stability is improved is shown. Cylindrical storage electrodes are formed in a matrix pattern on a substrate that includes an insulation interlayer having contacts therein so that a mold layer surrounds the cylindrical storage electrodes. Sacrificial plugs are formed with a cap within these electrodes. A stabilizing layer is formed on the etched mold layer and the cylindrical storage electrode by partially etching the mold layer. The stabilizing layer is etched until the sacrificial plug is exposed, thereby forming a spacer. While the sacrificial plug and the mold layer are fully removed, the spacer is partially removed, thereby forming a stabilizing member for supporting neighboring storage electrodes adjacent to each other. Accordingly, a structural stability of the capacitor is improved.

### CROSS REFERENCE TO RELATED APPLICATION

This application claims priority under 35 USC § 119 to Korean Patent Application No. 2004-67315 filed on Aug. 26, 2004, the contents of which are herein incorporated by reference in their entirety.

### BACKGROUND OF THE INVENTION

1. Field of the Invention

The present invention relates to a method of manufacturing a semiconductor device, and more particularly, to a method of forming a cylindrical capacitor for a semiconductor memory device.

2. Description of the Related Art

A semiconductor memory device such as a dynamic random access memory (DRAM) device stores data or sequential orders for a computer program. When the memory device is a volatile memory device, the electrical information is read out from the memory device or is replaced with other information. In general, a unit structure of a semiconductor memory device includes one transistor and one capacitor, and the capacitor for a volatile memory device such as a DRAM device includes a storage electrode, a dielectric layer and a plate electrode. Accordingly, the capacitance of a capacitor has a large effect on the capability of a memory device.

A recent technical trend of high integration in semiconductor devices greatly reduces a cell area for a unit cell of the memory device, wherein the capacitor of the memory device has been changed from a planar type to a box type or a cylindrical type for obtaining a high capacitance. However, the box type or the cylindrical type capacitor has a problem in that cylindrical capacitors adjacent to each other are easily broken since the cylindrical capacitor has its height much greater than its width, making contact with each other, which is widely known as a two bits failure. That is, a high aspect ratio of the cylindrical capacitor may easily lead to a two bits failure in a memory device. In particular, the two bits failure becomes more serious to the most recent DRAM devices having gigabyte capability of which line width structures are less than about 0.1 μm, because the aspect ratio of the Gigabyte DRAM device is enormously high.

FIG. 1 is a cross-sectional view illustrating a conventional cylindrical capacitor.

Referring to FIG. 1, this conventional capacitor includes a cylindrical storage electrode 20 making electrical contact with a contact pad 12 on a semiconductor substrate 10. The storage electrode 20 also makes electrical contact with a metal oxidation silicon (MOS) transistor (not shown) via the contact pad 12.

An increase of cell capacitance of a DRAM device necessarily leads to an increase of the height of the storage electrode 20 in view of the above cylindrical structure of a capacitor. However, when the height of the storage electrode 20 is excessively increased, the storage electrode 20 becomes broken, shown as a dotted line in FIG. 1. Thus two storage electrodes adjacent to each other make contact with each other, thereby creating a two-bit failure.

A mesh-shaped stabilizing member may be formed between the capacitors to support the storage electrodes 20 adjacent to each other, so that the structural stability of the capacitor is improved and the two-bit failure is prevented.

According to a conventional method of forming the stabilizing member, a first mold layer, a silicon nitride layer, and a second mold layer are sequentially formed on a semiconductor substrate on which a contact plug is formed. The silicon nitride layer is provided as the stabilizing member. Then, the first and second mold layers and the silicon nitride layer are sequentially etched away, thereby forming an opening through which the contact plug is partially exposed. A conductive layer is formed on bottom and side surfaces of the opening, and a sacrificial layer is formed on the conductive layer to a sufficient thickness to fill the opening. The sacrificial layer is removed until a top surface of the second mold layer is exposed through a chemical mechanical polishing (CMP) process, thereby forming a storage electrode. Subsequently, the second mold layer is removed until a top surface of the silicon nitride layer is exposed, and a silicon oxide layer is formed on the exposed surface of the silicon nitride layer. Then, the silicon oxide layer is anisotropically etched away, thereby forming a spacer on an upper sidewall of the storage electrode. The silicon nitride layer is partially exposed between the spacers. An anisotropic etching process is performed against the exposed silicon nitride layer using the spacer as an etching mask, so that the silicon nitride layer is partially removed and the first mold layer is exposed, thereby forming the mesh shaped stabilizing member surrounding the storage electrode.

However, the above method of forming the stabilizing member has problems as follows. Since the stabilizing member comprises silicon nitride, a deposition process for depositing the silicon nitride is additionally added, and the mold layer is formed through two separate processes, so that process efficiency is greatly reduced. In addition, the nitride deposition process requires a high temperature furnace, thus complicating the equipment used for manufacturing.

According to another conventional method of forming the stabilizing member, a mold layer is first formed on a semiconductor substrate on which a contact plug is formed as high as the capacitor, and the mold layer is partially etched away, thereby forming an opening through which the contact plug is partially exposed. A conductive layer is formed on bottom and side surfaces of the opening, and a sacrificial layer is formed on the mold layer to a sufficient thickness to fill up the opening. Then, the sacrificial layer is removed through a CMP process until a top surface of the mold layer is exposed, thereby forming a storage electrode and a sacrificial plug. The mold layer is partially etched and a nitride layer is coated on the mold layer, thereby forming the stabilizing member. However, this method of forming the stabilizing member also has a problem of having a relatively low capacitance. In detail, the sacrificial layer is more etched than the mold layer in the opening, and a recessed portion is formed in the opening, so that a nitride layer is formed in the recessed portion of the opening. Accordingly, a portion of a side surface of the storage electrode corresponding to the recessed portion is not effective for the capacitor, thereby reducing the capacitance due to a surface reduction.

### SUMMARY OF THE INVENTION

Accordingly, embodiments of the present invention provide a method of forming a capacitor for a semiconductor device, including a stabilizing member for improving the structural stability of the capacitor with a low heat budget and high process efficiency.

The structural stability of the capacitor is greatly improved despite its high aspect ratio. Furthermore, manufacturing efficiency is improved.

### BRIEF DESCRIPTION OF THE DRAWINGS

The above and other features and advantages of the present invention will become readily apparent by reference to the following detailed description when considering in conjunction with the accompanying drawings, in which:

FIG. 1 is a cross-sectional view illustrating a conventional cylindrical capacitor;

FIGS. 2, 4, and 6 are cross-sectional views taken along line I-I of FIG. 3, illustrating processing steps for a method of forming a capacitor for a semiconductor device according to an exemplary embodiment of the present invention;

FIGS. 9, 11, 13, and 15 are cross-sectional views taken along line I-I of FIG. 8, illustrating processing steps for a method of forming a capacitor for a semiconductor device according to an exemplary embodiment of the present invention;

FIG. 18 is a cross-sectional view taken along line I-I of FIG. 17, illustrating processing steps for a method of forming a capacitor for a semiconductor device according to an exemplary embodiment of the present invention;

FIG. 21 is a cross-sectional view taken along line I-I of FIG. 20, illustrating processing steps for a method of forming a capacitor for a semiconductor device according to an exemplary embodiment of the present invention;

FIGS. 24 and 26 are cross-sectional views taken along line I-I of FIG. 23, illustrating processing steps for a method of forming a capacitor for a semiconductor device according to an exemplary embodiment of the present invention;

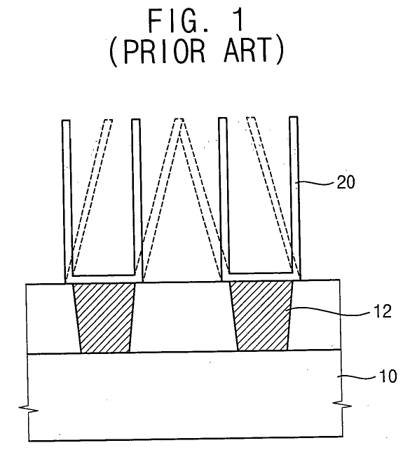

FIGS. 5 and 7 are cross-sectional views taken along line II-II of FIG. 3, illustrating processing steps for a method of forming a capacitor for a semiconductor device according to an exemplary embodiment of the present invention;

FIGS. 10, 12, 14, and 16 are cross-sectional views taken along line II-II of FIG. 8, illustrating processing steps for a method of forming a capacitor for a semiconductor device according to an exemplary embodiment of the present invention;

FIG. 19 is a cross-sectional view taken along line II-II of FIG. 17, illustrating processing steps for a method of forming a capacitor for a semiconductor device according to an exemplary embodiment of the present invention;

FIG. 22 is a cross-sectional view taken along line II-II of FIG. 20, illustrating processing steps for a method of forming a capacitor for a semiconductor device according to an exemplary embodiment of the present invention;

FIGS. 25, and 27 are cross-sectional views taken along line II-II of FIG. 23, illustrating processing steps for a method of forming a capacitor for a semiconductor device according to an exemplary embodiment of the present invention; and

FIGS. 3, 8, 17, 20, and 23 are plan views illustrating processing steps for a method of forming a capacitor for a semiconductor device according to an exemplary embodiment of the present invention.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

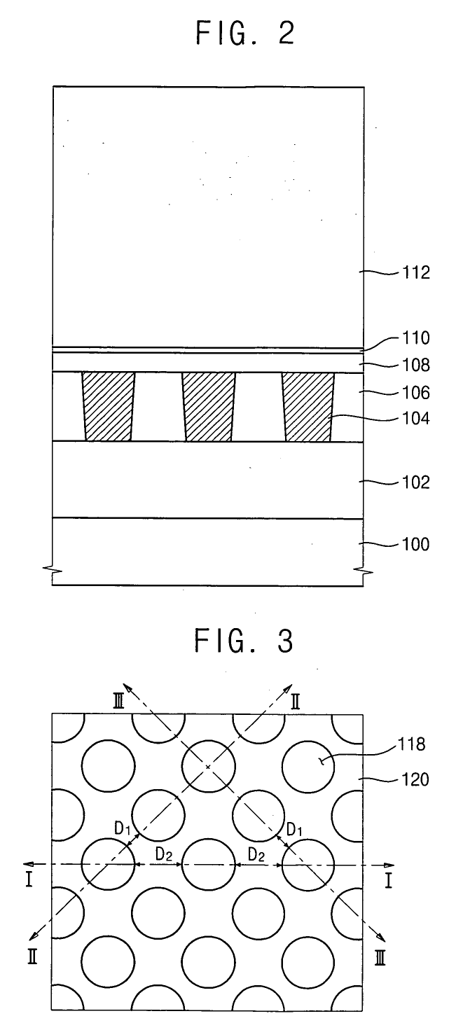

FIGS. 2 to 27 are views illustrating processing steps for a method of forming a capacitor according to an exemplary embodiment of the present invention. In FIGS. 2 to 27, the same reference numbers will be used to refer to the same or like parts.

Referring to FIG. 2, which is a cross-sectional view taken along line I-I in FIG. 3, a first insulation interlayer 102 including a semiconductor device (not shown) such as a MOS transistor is formed on a semiconductor substrate 100 such as a silicon wafer. Examples of the first insulation interlayer 102 include borophosphosilicate glass (BPSG), phosphosilicate glass (PSG), undoped silicate glass (USG), silicon-on-glass (SOG), tetra ethyl ortho silicate (TEOS) oxide by a plasma enhanced chemical vapor deposition (PECVD) process, an oxide by a high density plasma CVD (HDP-CVD) process, etc. These can be used alone or in combinations thereof.

The semiconductor device includes a word line structure extending in a first direction and a bit line structure extending in a second direction substantially perpendicular to the first direction. The word line structure includes a gate electrode, a gate mask and a gate spacer and crosses the semiconductor substrate 100, and the bit line structure includes a bit line pattern, a bit line mask and a bit line spacer. The semiconductor device further includes an impurity-doped region arranged in the second direction symmetrically with respect to the word line structure. Some portions of the impurity-doped region are connected to a capacitor that is formed in a subsequent process, and other portions of the impurity-doped region are connected to the bit line structure.

A second insulation interlayer 106 is formed on the first insulation interlayer 102 including a contact plug 104 electrically connected to a portion of the impurity-doped region. The MOS transistor on the substrate 100 is electrically connected to the capacitor via the contact plug 104 (which may be a contact pad). Examples of a material for the second insulation interlayer 106 include those of the first insulation interlayer.

A third insulation interlayer 108 is formed on the second insulation interlayer 106 and the contact plug 104, so that the bit line pattern is electrically isolated from a storage electrode that is to be formed in a subsequent process. Examples of a material for the third insulation interlayer 108 include those of the first insulation interlayer. The third insulation interlayer 108 may be substantially identical to at least one of the first insulation interlayer 102 and the second insulation interlayer 106.

An etching stop layer 110 is formed on the third insulation interlayer 108, and a mold layer 112 for forming a storage electrode 126 is formed on the etching stop layer 110 to a thickness of about 5000 Å to about 50000 Å. The etching stop layer 110 is exemplarily comprised of silicon nitride, and the mold layer 112 has an etching selectivity with respect to the etching stop layer 110. Examples of a material for the mold layer 112 include those of the first insulation interlayer. The thickness of the mold layer 112 is varied in accordance with the desired capacitance of the capacitor. Because a height of the capacitor is varied in accordance with its thickness, and its capacitance is varied in accordance with its height, the capacitance is determined in accordance with the thickness of the mold layer 112. Furthermore, a stabilizing member that is to be formed in a subsequent process simultaneously supports neighboring capacitors adjacent to each other, so that the capacitor is prevented from being broken despite of high aspect ratio thereof. As a result, the height of the capacitor may be increased even at the same diameter thereof.

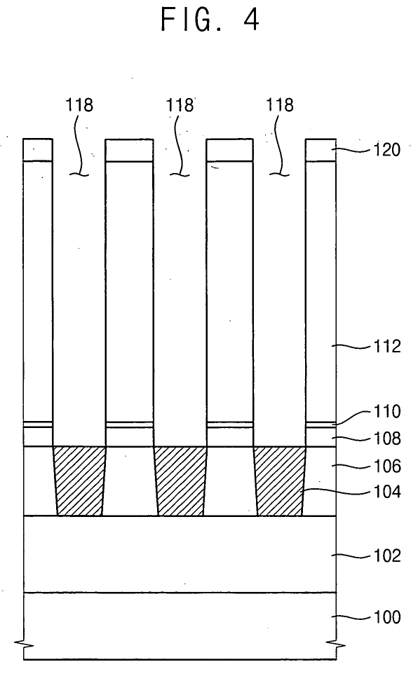

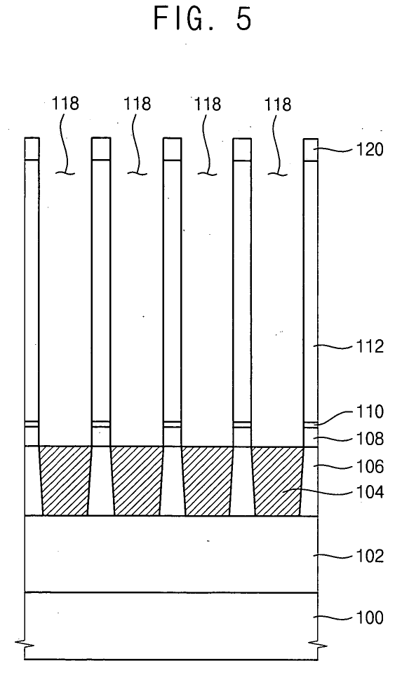

Referring to FIGS. 3 to 5, the mold layer 112, the etching stop layer 110 and the third insulation interlayer 108 are sequentially and partially etched away, thereby forming a first opening 118 through which the contact plug 104 is exposed. FIG. 4 is a cross sectional view taken along line I-I of FIG. 3, and FIG. 5 is a cross-sectional view taken along line II-II of FIG. 3.

A mask layer (not shown) is formed on the mold layer 112, and a photoresist layer (not shown) is formed on the mask layer. The photoresist layer is formed into a photoresist pattern by a photolithography process. Then, an anisotropic etching process is performed against the mask layer using the photoresist pattern as an etching mask, thereby forming a mask pattern 120. Thereafter, the photoresist pattern is removed from the mask pattern 120 by an ashing process and a strip process. An anisotropic etching process is also performed on the mold layer 112 using the mask pattern 120 as an etching mask, thereby forming the first opening 118. As an exemplarily embodiment, the mask layer includes a silicon nitride layer formed by a low-pressure chemical vapor deposition (LPCVD) process. An anti-reflection layer may be further formed on the mask layer for improving the patterning efficiency of the photoresist layer.

In another way, a photoresist pattern is formed on the mold layer 112, and the mold layer 112 is anisotropically and partially etched away using the photoresist pattern as an etching mask, thereby forming the first opening 118 through which the contact plug 104 is exposed.

As shown in FIG. 3, the first opening 118 is arranged in a matrix pattern that includes a plurality of columns and rows. As an exemplary embodiment, a first gap distance D1 between the openings 118 along a row direction (parallel with a line II-II in FIG. 3) or a column direction (parallel with a line III-III in FIG. 3) is smaller than a second gap distance D2 between the openings 118 along a diagonal direction (parallel with a line I-I in FIG. 3). Although not shown in FIG. 3, the diagonal direction is substantially in parallel with an extension direction of the word line or the bit line.

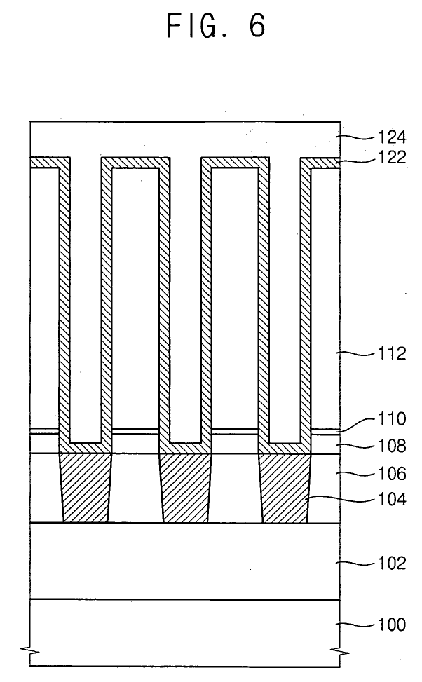

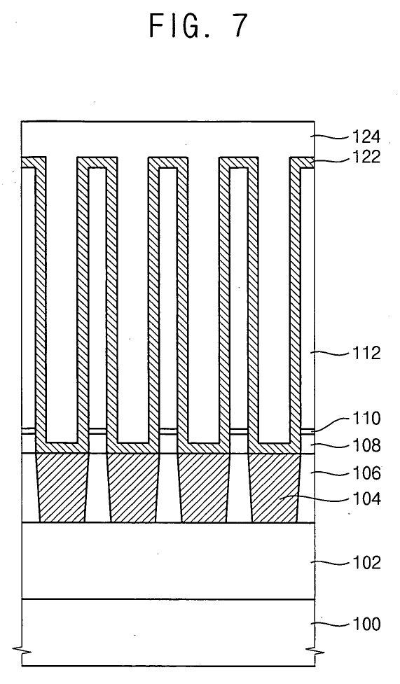

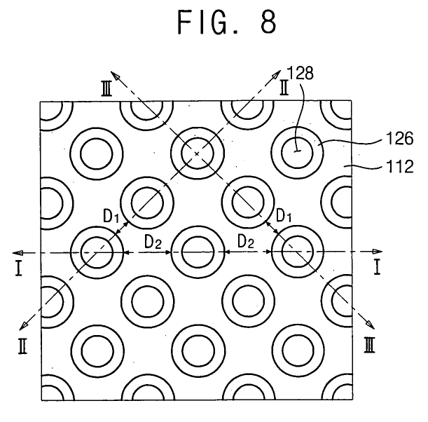

FIG. 6 is a cross sectional view taken along line I-I of FIG. 3, and FIG. 7 is a cross-sectional view taken along line II-II of FIG. 3.

Referring to FIGS. 6 and 7, the mask pattern 120 is removed from the mold layer 112, and a conductive layer 122 is formed on the exposed contact plug 104, inner surfaces of the opening 118 and on a top surface of the mold layer 112. As an exemplary embodiment, the mask pattern 120 is removed by using a chemical solution comprising phosphoric acid, and the conductive layer 122 is comprised of a doped polysilicon heavily doped with N type or P type impurities. In the present embodiment, the conductive layer 122 is formed through an LPCVD process and a doping process for a uniform thickness.

A sacrificial layer 124 is formed on the conductive layer 122 to a sufficient thickness to fill the first opening 118, thereby protecting the storage electrode during its formation from the conductive layer 122. Examples of a material for the sacrificial layer 124 include those of the first insulation interlayer. In the present embodiment, the sacrificial layer 124 is substantially identical to the mold layer 112. The mask pattern 120 may remain on the mold layer 112, thereby functioning as a polishing stop pattern for a planarizing process.

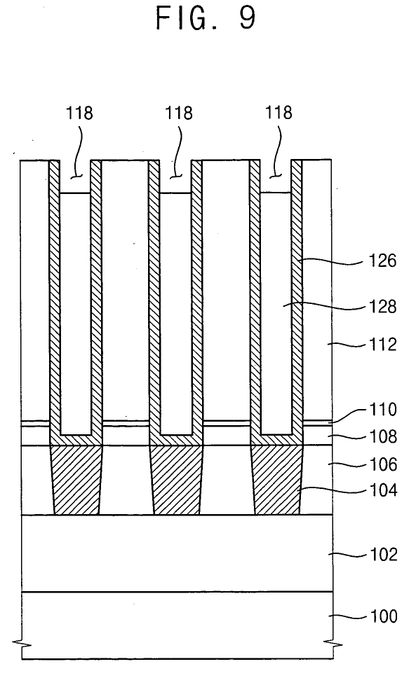

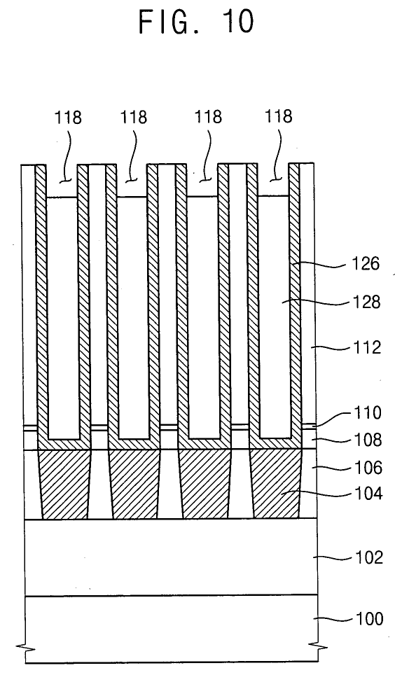

FIG. 9 is a cross sectional view taken along line I-I of FIG. 8, and FIG. 10 is a cross-sectional view taken along line II-II of FIG. 8.

Referring to FIGS. 8 to 10, the sacrificial layer 124 and the conductive layer 122 are partially etched away until a top surface of the mold layer 122 is exposed, so that the sacrificial layer 124 and the conductive layer 122 remain only in the opening 118, thereby forming a cylindrical storage electrode 126 and a sacrificial plug 128 in the opening 118. In the present invention, the opening 118 is partially empty over the resulting top surface of the sacrificial plug 128, and thus an upper portion of the cylindrical storage electrode 126 is still open.

The sacrificial plug 128 of which top surface is lower than that of the mold layer 112 is formed in the cylindrical storage electrode 126 in various ways. In the present embodiment, the sacrificial layer 124 has an etching rate higher than that of the conductive layer 122 for the same etchant, so that the sacrificial layer 124 is etched much more than the conductive layer 122 in the same time. As a result, the sacrificial layer 124 is etched to a depth greater than the thickness of the conductive layer 122 while the conductive layer 122 on the mold layer 112 is etched away, and thus a top surface of the sacrificial plug 128 is lower than a top surface of the mold layer 112. In particular, when the mask pattern 120 still remains on the mold layer 112, the top surface of the sacrificial plug 128 is much lower than a top surface of the mold layer 112, as much as the thickness of the mask pattern 120, because the sacrificial layer 124 is further etched away while the mask pattern 120 is removed until the top surface of the mold layer 112 is exposed. Although the above exemplary embodiment discusses the sacrificial plug formed by an anisotropic etching process, the sacrificial plug could also be formed by any other modified technique known to one of the ordinary skill in the art.

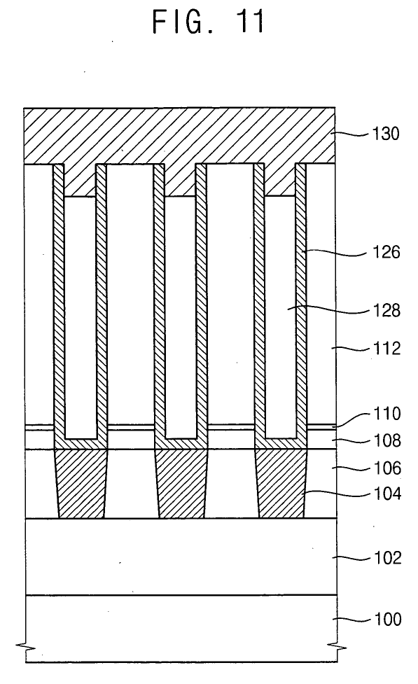

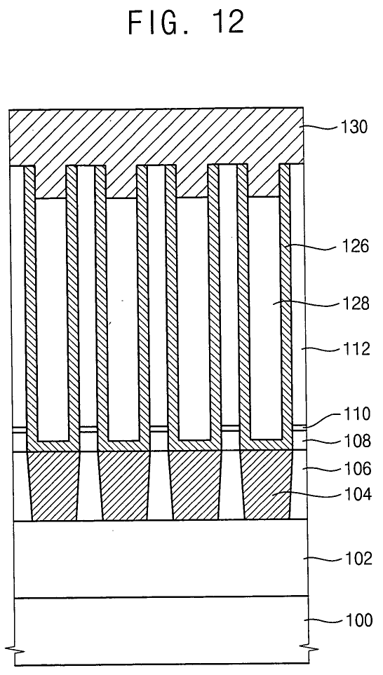

FIG. 11 is a cross sectional view taken along line I-I of FIG. 8, and FIG. 12 is a cross-sectional view taken along line II-II of FIG. 8.

Referring to FIGS. 11 and 12, a capping layer 130 is formed on the mold layer 112, the storage electrode 126, and the sacrificial plug 128, to a sufficient thickness to at least fill the inside of the storage electrode 126. In the present embodiment, the capping layer is formed to a thickness of about 100 Å to about 3000 Å.

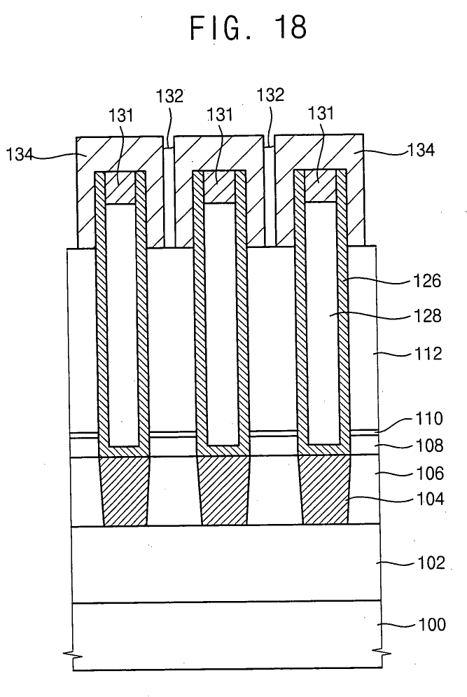

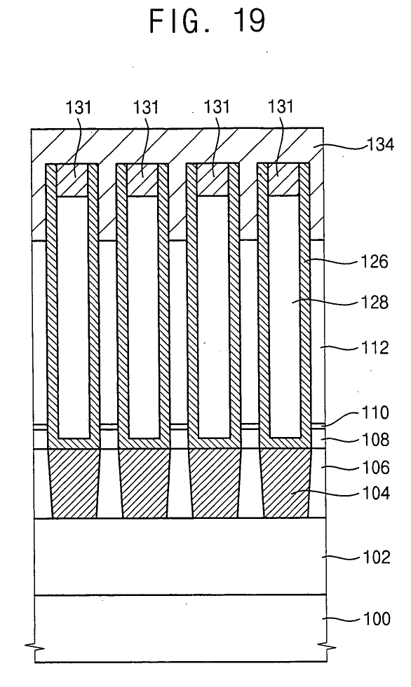

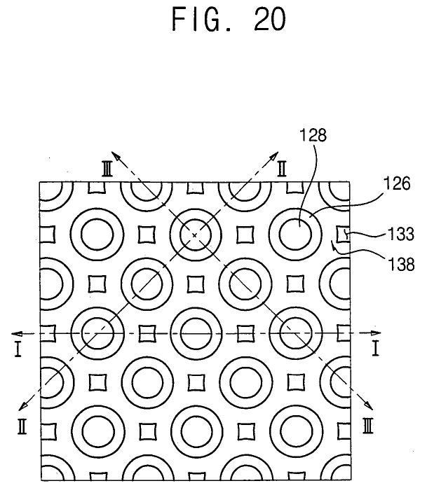

The capping layer 130 has an etching rate higher than that of a stabilizing layer 134 in FIG. 18 that is to be formed in a subsequent process. For example, the capping layer 130 is comprised of silicon germanium if the stabilizing layer 134 comprises a nitride. In the present embodiment, the capping layer 130 comprising silicon germanium may be formed by an ultra high vacuum chemical vapor deposition (UVCVD) process, an LPCVD process, or a gas source molecular beam epitaxial (GS-MBE) process using a silicon source gas such as a SiH4 gas, a germanium source gas such as a GeH4 gas, and a carrier gas such as a H2 gas.

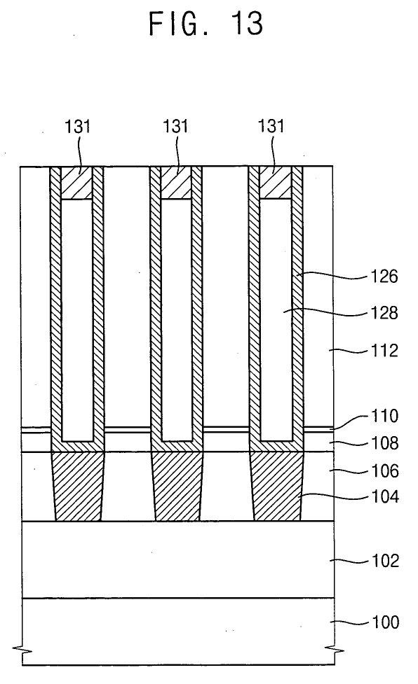

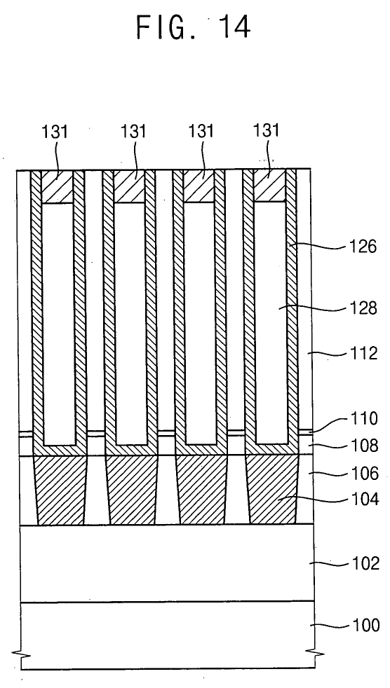

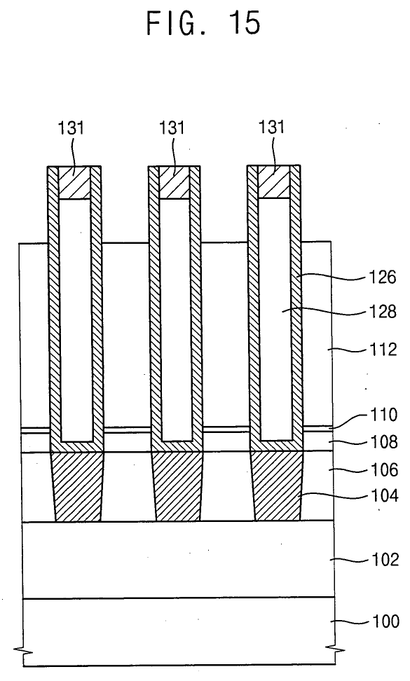

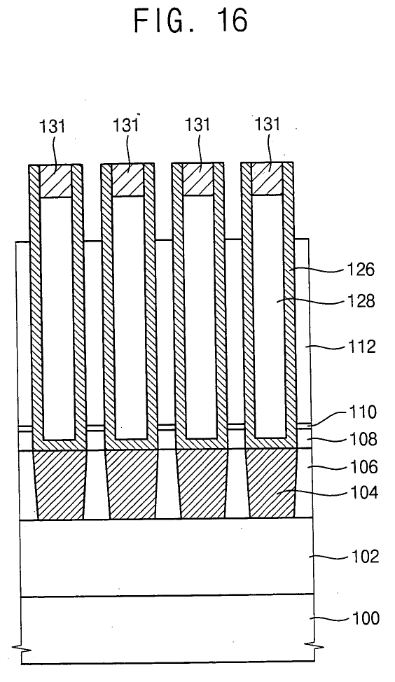

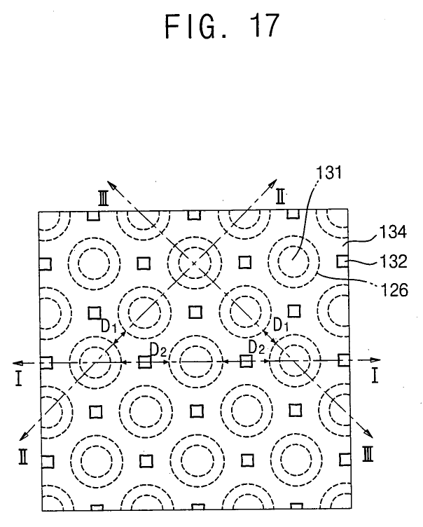

FIG. 13 is a cross sectional view taken along line I-I of FIG. 8, and FIG. 14 is a cross-sectional view taken along line II-II of FIG. 8.

Referring to FIGS. 13 and 14, the capping layer 130 is planarized by a CMP process or a dry etching process until the top surface of the mold layer 112 is exposed, so that the capping layer remains only on the sacrificial plug 128. As a result, the inside of the storage electrode 126 is filled with the capping layer, thereby forming a cap 131 on the sacrificial plug 128. The inside of the storage electrode 126 is protected from the surroundings by the cap 131, so that the storage electrode 126 is prevented from being contaminated or damaged during a subsequent formation process of a stabilizing member 144.

In another way, when the conductive layer 122 still remains on the mold layer 112 prior to a node separation, the planarization process for forming the cap 131 may be performed simultaneously with the node separation process.

The cap 131 for protecting the inside of the cylindrical storage electrode 126 is formed on an upper portion of the storage electrode 126 in a great number of ways, so that disclosing all of the methods of forming the cap 131 in the specification is impractical. However, the cap 131 may be formed by any other modified methods based on the above-mentioned process, as would be known to one of ordinary skill in the art.

FIG. 15 is a cross sectional view taken along line I-I of FIG. 8, and FIG. 16 is a cross-sectional view taken along line II-II of FIG. 8.

Referring to FIGS. 15 and 16, the mold layer 112 is partially removed, thereby exposing an upper portion of the storage electrode 126. In the present embodiment, the mold layer 112 is wet-etched away using a chemical solution such as an aqueous HF solution.

The mold layer 112 is exemplarily etched to a depth corresponding to a height of the stabilizing member 144, and in detail, to a depth of about 100 Å to about 5000 Å. In such a case, the etching depth is controlled merely by adjusting an etching time of the wet etching process because an etching rate of the mold layer 112 with a predetermined etchant is well known to one of ordinary skill in the art in various documents or catalogs.

The sacrificial plug 128 is protected from being etched during the wet etching process for etching the mold layer 112 by the cap 131, so that the storage electrode 126 is prevented from being contaminated or damaged during the wet etching process.

FIG. 18 is a cross sectional view taken along line I-I of FIG. 17, and FIG. 19 is a cross-sectional view taken along line II-II of FIG. 17.

Referring to FIGS. 17 to 19, the stabilizing layer 134 is formed on a top surface of the mold layer 112, on top and side surfaces of the storage electrode 126 and on a top surface of the cap 131. As an exemplary embodiment, the stabilizing member 134 is comprised of a material having good step coverage and an etching selectivity with respect to the mold layer 112. For example, the etching selectivity of the stabilizing layer 134 with respect to the mold layer 112 is more than or equal to about 200:1 with a predetermined etchant. In the present embodiment, when the mold layer 112 is comprised of an oxide deposited by an HDP-CVD process, the stabilizing layer 134 comprises silicon nitride. Accordingly, when an aqueous HF solution or a mixture solution of NH4OH, H2O2 and de-ionized water is used as the etchant, the mold layer 112 is more rapidly etched than the stabilizing layer 134.

The stabilizing layer 134 is added to a sufficient thickness to cover the upper portion of the storage electrode 126 in a range from the first gap distance D1 to the second gap distance D2, so that a first recess 132 is formed between the storage electrodes 126 in the diagonal direction (along the line I-I).

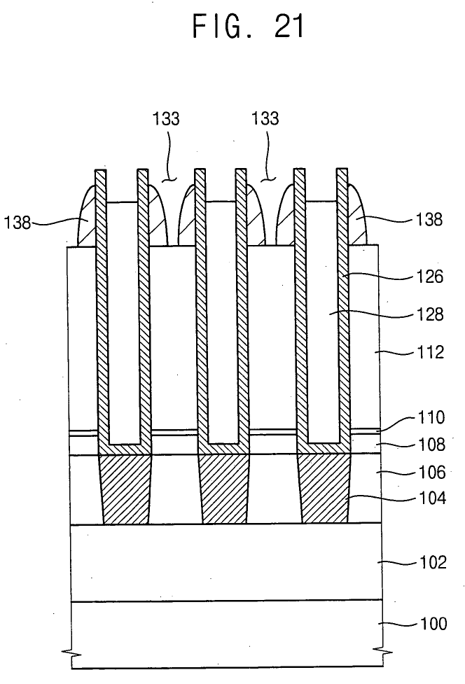

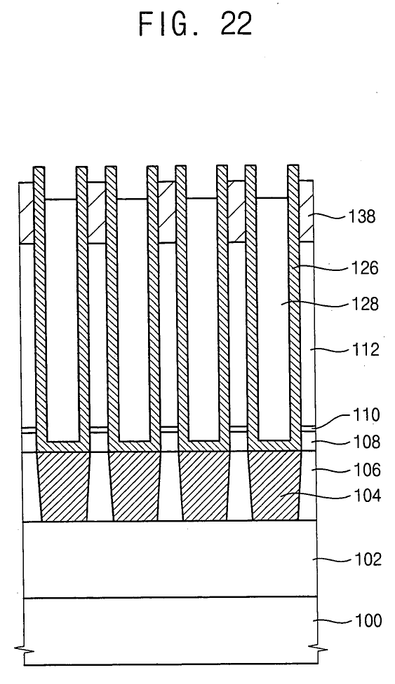

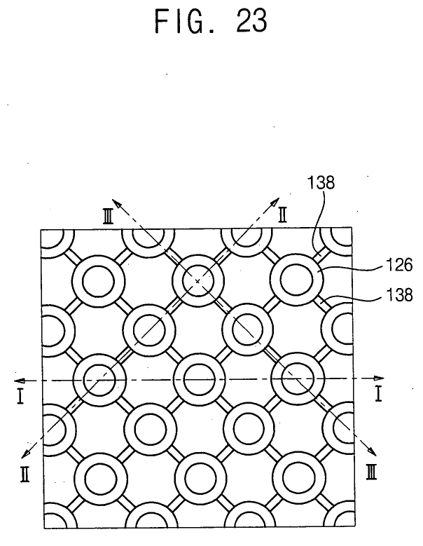

FIG. 21 is a cross sectional view taken along line I-I of FIG. 20, and FIG. 22 is a cross-sectional view taken along line II-II of FIG. 20.

Referring to FIGS. 20 to 22, an isotropic and etching process is partially performed on the stabilizing layer 134, thereby forming a spacer 138 on a side surface of the upper portion of the storage electrode 126. In the present embodiment, the spacer 138 is formed into an arch shape in the row direction (along the line II-II) or in the column direction (along the line III-III), and is formed into a rectangular shape in the diagonal direction (along the line I-I). As a result, the first recess 132 is enlarged to form a second recess 133. The line II-II or the line III-III corresponds to a short axis of the storage electrode 126, and the line I-I corresponds to a long axis of the storage electrode 126.

When the stabilizing layer 134 is partially etched away, the cap 131 is simultaneously etched off with the stabilizing layer 134, thereby exposing the sacrificial plug 128. A thickness and a shape of the spacer 138 are determined in accordance with an etching time for removing the cap 131, so that a control on an etching selectivity of the stabilizing layer 134 with respect to the cap 131 using a predetermined etchant generates a proper thickness and shape of the spacer 138, as would be known to one of ordinary skill in the art.

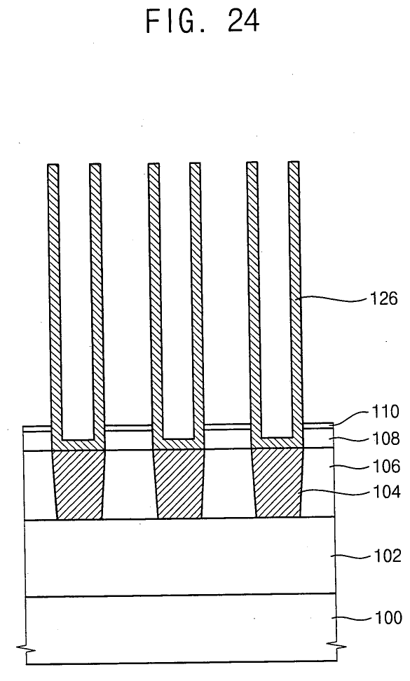

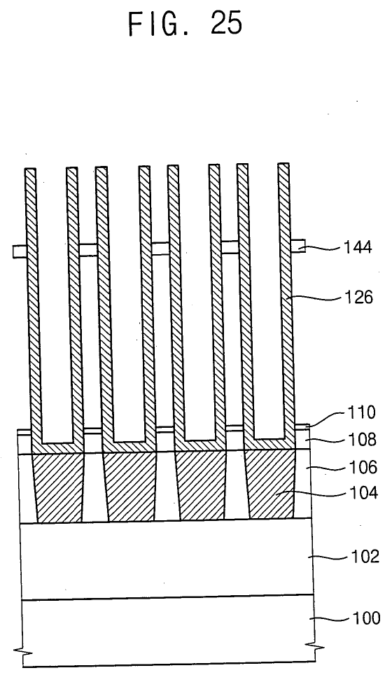

FIG. 24 is a cross sectional view taken along line I-I of FIG. 23, and FIG. 25 is a cross-sectional view taken along line II-II of FIG. 23.

Referring to FIGS. 23 to 25, an isotropic etching process is also performed against the mold layer 112 and the sacrificial plug 128 using the spacer 138 as an etching mask, thereby forming the stabilizing member 144 supporting neighboring storage electrodes 126 adjacent to each other and stabilizing the storage electrodes 126. In detail, the mold layer 112 and the sacrificial plug 128 are etched away using a chemical solution in which the mold layer 112 and the sacrificial plug 128 have an etching selectivity with respect to the spacer 138, so that the mold layer 112 and the sacrificial plug 128 are almost removed and the spacer 138 is partially removed. The chemical solution is supplied into the storage electrode 126, thereby removing the sacrificial plug 128 therein. Further, the chemical solution is applied onto the top surface of the mold layer 112 through the second recess 133, thereby removing the mold layer 112 below the stabilizing member 144. In such a case, the sacrificial plug 128 is removed prior to a complete removal of the mold layer 112, because a density of the sacrificial plug 128 is lower than that of the mold layer 112. While all of the arch-shaped spacers 138 in the row direction or in the column direction are removed, the rectangular shaped spacer 138 in the diagonal direction is only partially removed, so that the spacer 138 is partially removed, thereby forming the stabilizing member 144 into a mesh shape in which the storage electrodes 126 are connected to each other in the row and column directions. In the present embodiment, the mold layer 112 and the sacrificial plug 128 may be etched away using a diluted NH4 solution or a diluted aqueous HF solution. An example of the diluted NH4 solution includes a standard cleaning solution (SC-1) comprising ammonium hydroxide (NH4OH), hydrogen peroxide (H2O2) and de-ionized water (H2O).

As shown in FIG. 23, the stabilizing member 144 is formed into a mesh shape in which the storage electrodes 126 are connected to each other in the row and column directions, so that the storage electrodes 126 are supported by the stabilizing member 144 in the row and column directions and a position stability of the storage electrode 126 is remarkably improved despite of a high aspect ratio.

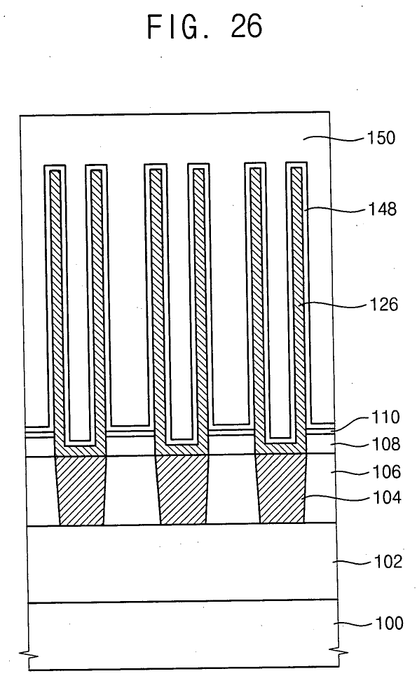

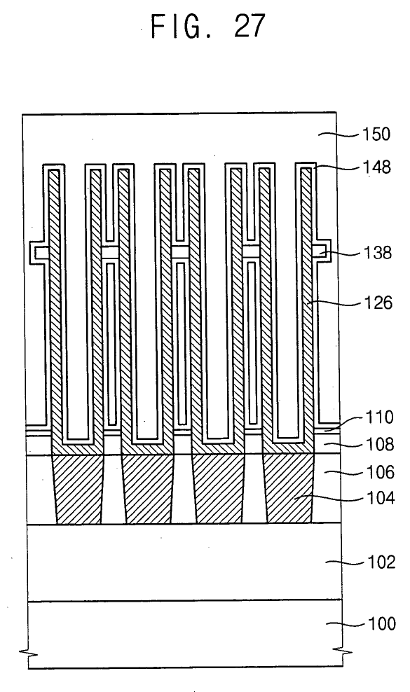

FIG. 26 is a cross sectional view taken along line I-I of FIG. 23, and FIG. 27 is a cross-sectional view taken along line II-II of FIG. 23.

Referring to FIGS. 26 and 27, a dielectric layer 148 and a plate electrode 150 are sequentially formed on the storage electrode 126 and the stabilizing member 144, thereby completing a capacitor for a semiconductor device. In detail, the dielectric layer 148 is comprised of silicon oxide or a material of a high dielectric constant. The plate electrode 150 may be comprised of a doped polysilicon or a metal.

According to the present embodiment, the stabilizing member is formed not in the mold layer but between the storage electrodes adjacent to each other, thereby improving process efficiency. Furthermore, the storage electrode is protected from being contaminated or damaged by the cap during an etching process for etching the stabilizing layer, so that the capacitance of the capacitor is prevented from being reduced.

Although the exemplary embodiments of the present invention have been described, it is understood that the present invention should not be limited to these exemplary embodiments but various changes and modifications can be made by one skilled in the art within the spirit and scope of the present invention as hereinafter claimed.

What is claimed is:

1. A method of forming a capacitor for a semiconductor device comprising:
forming a mold layer including an opening on a semiconductor substrate;
forming a conductive layer continuously on side and bottom surfaces of the opening;
forming a sacrificial layer on the conductive layer to fill up the opening;
partially etching the sacrificial layer and the conductive layer, thereby forming a cylindrical storage electrode and a sacrificial pattern in the cylindrical storage electrode, the sacrificial pattern being lower than the mold layer;
forming a capping pattern on the sacrificial pattern so that the opening is filled with the capping pattern;
partially removing the mold layer, thereby exposing an upper portion of the storage electrode; and
forming a stabilizing member on the exposed storage electrode, so that neighboring storage electrodes adjacent to each other are simultaneously supported by the stabilizing member.

2. The method of claim 1, wherein the capping pattern is comprised of silicon germanium (SiGe).

3. The method of claim 1, wherein forming the capping pattern includes:
forming a capping layer on the mold layer and the sacrificial pattern to a thickness such that an inside of the cylindrical storage electrode is filled with the capping layer; and
planarizing the capping layer until a top surface of the mold layer is exposed, so that the capping layer remains only in the opening.

4. The method of claim 1, wherein forming the stabilizing member includes:
forming a stabilizing layer on a top surface of the mold layer, on top and side surfaces of the storage electrode and on a top surface of the capping pattern to a thickness to cover an upper portion of the storage electrode;
etching the stabilizing layer and the capping pattern until a top surface of the sacrificial pattern is exposed, the stabilizing layer having an etching selectivity with respect to the capping pattern, thereby forming a stabilizing pattern surrounding an upper portion of the storage electrode on the mold layer; and
etching the stabilizing pattern and the mold layer, the mold layer having an etching selectivity with respect to the stabilizing pattern, thereby forming the stabilizing member at the side surface of the storage electrode.

5. The method of claim 4, wherein the sacrificial pattern is prevented from being etched by the capping pattern while the stabilizing pattern is formed.

6. The method of claim 4, wherein the stabilizing pattern on the upper portion of the storage electrode substantially fully fills a gap between the storage electrodes in row and column directions thereof, and partially fills the gap between the storage electrodes in a diagonal direction thereof, so that a recessed portion is formed between the storage electrodes in the diagonal direction.

7. The method of claim 4, wherein the stabilizing layer is formed to a thickness in a range from about a first gap distance to about a second gap distance, the first gap distance including a distance between the openings along a row or a column direction of the storage electrode and the second gap distance including a distance between the openings along a diagonal direction of the storage electrode.

8. The method of claim 4, wherein the stabilizing layer comprises silicon nitride.

9. The method of claim 4, wherein the stabilizing layer and the capping pattern are dry-etched away, thereby forming the stabilizing pattern.

10. The method of claim 4, wherein the stabilizing pattern and the mold layer are wet etched away, thereby forming the stabilizing member.

11. The method of claim 10, wherein the wet-etching process is performed using a standard cleaning solution comprising ammonium hydroxide (NH4OH), hydrogen peroxide (H2O2) and de-ionized water (H2O).

12. The method of claim 4, wherein the stabilizing member is formed into a mesh shape in which the storage electrodes are connected to each other in row and column directions thereof and are spaced apart in a diagonal direction thereof.

13. The method of claim 1, wherein the mold layer comprises silicon oxide.

14. The method of claim 1, wherein an insulation interlayer including a plurality of contact plugs is formed on the substrate.

15. The method of claim 1, further comprising:
forming a dielectric layer on the stabilizing member and the storage electrode; and
forming a plate electrode on the dielectric layer.

16. A capacitor for a semiconductor device produced by the method of claim 4.

17. A method of forming a stabilizing structure for a capacitor in a semiconductor device, comprising:
forming a mold layer on a substrate, the mold layer having an opening to expose a contact plug disposed on the substrate;
forming a conductive layer on the mold layer, so that the opening is only partially filled, thus forming an electrode;
completely filling the opening with a sacrificial layer;
etching the sacrificial layer and the conductive layer until the mold layer is exposed, wherein the sacrificial layer is etched so that a top portion of the opening is empty;
filling the empty portion of the opening with a cap layer;
etching a top portion of the mold layer to expose a top portion of the conductive layer;
coating the exposed top portion of the conductive layer and the cap layer with a stabilizing layer; and
etching the stabilizing layer and the cap layer to form a spacer, the spacer directly contacting adjacent electrodes.

18. The method of claim 17, further comprising:
completely etching the sacrificial layer that is inside the electrode;
adding a dielectric layer; and
adding a top electrode, thus forming the capacitor.

19. A capacitor for a semiconductor device, comprising:
a conductive plug disposed on a substrate;
a substantially cylindrical conductive layer disposed directly on the conductive plug;
a nonconductive spacer in direct contact with at least two of the cylindrical conductive layers, the nonconductive spacer disposed at a height that is below the top of the cylindrical conductive layer;
a top conductive layer covering the cylindrical conductive layer; and
a dielectric layer intervening between the top conductive layer and the cylindrical conductive layer, wherein the top conductive layer and the cylindrical conductive layer are electrically insulated from each other by the dielectric layer.

20. The capacitor of claim 19 wherein the nonconductive spacer is disposed at a height that is only in the range between about one half and about three-fourths of the distance up the cylindrical conductive layer

21. The capacitor of claim 19, wherein a volume between the at least two cylindrical conductive layers below the nonconductive spacer is filled with silicon oxide.
